(19) United States
(12) Patent Application Publication
(10) Pub. No.: US 2026/0095192 A1
(43) Pub. Date: Apr. 2, 2026

(54) METHODS AND APPARATUS TO PERFORM ANALOG-TO-DIGITAL CONVERSIONS IN A CONTINUOUS TIME PIPELINE

(71) Applicant: Texas Instruments Incorporated, Dallas, TX (US)

(72) Inventors: Amit Kumar Gupta, Frisco, TX (US); Taras Dudar, Plano, TX (US)

(21) Appl. No.: 18/899,687

(22) Filed: Sep. 27, 2024

(51) Int. Cl. H03M 3/00

(52) U.S. Cl. CPC H03M 3/354

(57) ABSTRACT

An example apparatus includes: a first switch having a first terminal and a second terminal; analog-to-digital converter (ADC) circuitry having an input and an output, the input of the ADC circuitry coupled to the first terminal of the first switch; digital-to-analog converter (DAC) circuitry having an input and an output, the input of the DAC circuitry coupled to the output of the ADC circuitry; combination circuitry having a first input, a second input, and an output, the first input of the combination circuitry coupled to the second terminal of the first switch, the second input of the combination circuitry coupled to the output of the DAC circuitry; amplifier circuitry having an input and an output, the input of the amplifier circuitry coupled to the output of the combination circuitry; and a second switch having a terminal coupled to the output of the amplifier circuitry.

### TECHNICAL FIELD

This description relates generally to analog-to-digital conversions and, more particularly, to methods and apparatus to perform analog-to-digital conversions in a continuous time pipeline.

### BACKGROUND

As electronics continue to advance, systems have become capable of safely operating under increasingly higher powers and higher accuracies. In analog-to-digital converters (ADCs), increasingly complex circuitry implements advanced techniques to prevent aliasing, noise, and clock jitter from affecting conversions. Continuous time ADCs utilize analog circuitry to perform a series of continuous time operations on analog signals, such as filtering or delaying, during the analog-to-digital conversion. Such analog circuitry plays a role in producing accurate digital outputs.

### SUMMARY

For methods and apparatus to perform analog-to-digital conversions in a continuous time pipeline, an example apparatus includes a first switch having a first terminal and a second terminal; analog-to-digital converter (ADC) circuitry having an input and an output, the input of the ADC circuitry coupled to the first terminal of the first switch; digital-to-analog converter (DAC) circuitry having an input and an output, the input of the DAC circuitry coupled to the output of the ADC circuitry; combination circuitry having a first input, a second input, and an output, the first input of the combination circuitry coupled to the second terminal of the first switch, the second input of the combination circuitry coupled to the output of the DAC circuitry; amplifier circuitry having an input and an output, the input of the amplifier circuitry coupled to the output of the combination circuitry; and a second switch having a terminal coupled to the output of the amplifier circuitry. Other examples are described.

For methods and apparatus to perform analog-to-digital conversions in a continuous time pipeline, an example apparatus includes first analog-to-digital converter (ADC) circuitry having an input and an output; digital-to-analog converter (DAC) circuitry having an input and an output, the input of the DAC circuitry coupled to the output of the first ADC circuitry; first combination circuitry having a first input, a second input, and an output, the first input of the first combination circuitry coupled to the input of the first ADC circuitry, the second input of the first combination circuitry coupled to the output of the DAC circuitry; amplifier circuitry having an input and an output, the input of the amplifier circuitry coupled to the output of the first combination circuitry; second ADC circuitry having an input and an output, the input of the second ADC circuitry coupled to the output of the amplifier circuitry; and second combination circuitry having a first input and a second input, the first input of the second combination circuitry coupled to the output of the first ADC circuitry, the second input of the second combination circuitry coupled to the output of the second ADC circuitry. Other examples are described.

For methods and apparatus to perform analog-to-digital conversions in a continuous time pipeline, an example apparatus includes first analog-to-digital converter (ADC) circuitry; digital-to-analog converter (DAC) circuitry coupled to the first ADC circuitry; amplifier circuitry coupled to the DAC circuitry, the amplifier circuitry configured to amplify a residue by a gain, the residue is a difference between a first analog value and a second analog value; second ADC circuitry coupled to the amplifier circuitry; and combination circuitry coupled to first ADC circuitry and the second ADC circuitry, the combination circuitry configured to: multiply a first digital value by the gain to produce a combined digital value, the first digital value corresponds to the first analog value; combine a second digital value and the combined digital value, the second digital value corresponds to the residue; and generate a third digital value responsive to the combination of the second digital value and the combined digital value. Other examples are described.

### BRIEF DESCRIPTION OF THE DRAWINGS

FIG. 1 is a schematic diagram of example continuous time pipeline (CTP) ADC circuitry including first example combination circuitry, an example digital-to-analog converter (DAC), example residue amplifier circuitry, and second example combination circuitry.

FIG. 2 is a timing diagram of example clock signals structured to control the CTP ADC circuitry of FIG. 1.

FIG. 3 is a schematic diagram of example second stage circuitry of the CTP ADC circuitry of FIG. 1 including an example of the first combination circuitry of FIG. 1, an example of the DAC of FIG. 1, and an example of the residue amplifier circuitry of FIG. 1.

FIG. 4 is a schematic diagram of example second stage circuitry of the CTP ADC circuitry of FIG. 1 including an example of the first combination circuitry of FIGS. 1 and 3, another example of the DAC of FIGS. 1 and 4, and an example of the residue amplifier circuitry of FIGS. 1 and 3.

FIG. 5 is a block diagram of an example of the second combination circuitry of FIG. 1.

FIG. 6 is a flowchart representative of example machine-readable instructions or example operations that may be at least one of executed, instantiated, or performed using an example implementation of the first example combination circuitry of FIGS. 1, 3, and 4, the example DAC of FIGS. 1, 3, and 4, the example residue amplifier circuitry of FIGS. 1, 3, and 4, and the second example combination circuitry of FIGS. 1 and 5, or more generally the CT ADC circuitry of FIG. 1.

FIG. 7 is a schematic diagram of example dual path CTP ADC circuitry including the CTP ADC circuitry of FIG. 1.

FIG. 8 is a flowchart representative of example machine-readable instructions or example operations that may be at least one of executed, instantiated, or performed using an example implementation of the dual path CTP ADC circuitry of FIG. 7.

FIG. 9 is a schematic diagram of an example device test system including the CTP ADC circuitry of FIGS. 1 and 7 to sense power consumption of a device under test (DUT).

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

As electronics continue to advance, systems have become capable of safely operating under increasingly higher powers and higher accuracies. In analog-to-digital converters (ADCs), increasingly complex circuitry implements advanced techniques to prevent aliasing, noise, and clock jitter from affecting conversions. Continuous time ADCs utilize analog circuitry to perform a series of continuous time operations on analog signals, such as filtering or delaying, during the analog-to-digital conversion. Such analog circuitry plays a role in producing accurate digital outputs.

Continuous time delta-sigma (CTDS) ADC circuitry generates a digital output that represents a summation (sigma) of differences between (delta) an analog input and a previous value, which supplies a feedback path from the output. Some CTDS ADC circuitry includes combination circuitry, feedback circuitry, loop filter circuitry, a switch, quantizer circuitry, digital-to-analog converter (DAC) circuitry, and digital filter circuitry. The loop filter circuitry integrates a difference between an approximation of a previous analog input and the current analog input to determine the change in the analog input over time. The switch sequences the quantizer circuitry sampling of the output of the loop circuitry.

The quantizer circuitry generates a digital value representing the change in the analog input over time. The DAC circuitry generates an analog representation of the digital value. The combination circuitry subtracts the determined analog representation of the analog input from the actual value of the analog input. Finally, the digital filter circuitry digitally filters the digital value to produce the digital output representing the analog input. Time constants formed by capacitive and resistive elements of the loop filter circuitry constrain the range of possible switching frequencies of the sampling. Also, the continuous time DAC circuitry (e.g., current steering DACs, resistive DACs, etc.) of CTDS ADC circuitry are sensitive to clock jitters.

Continuous time pipeline (CTP) ADC circuitry uses a plurality of stages coupled in series to generate a series of low-resolution digital values that when combined form a high-resolution digital output. Each stage of the CTP ADC circuitry corresponds to a different portion of the overall resolution of the digital output. For example, a first stage of the CTP ADC circuitry produces a first digital value representing the most significant bits of the digital output and a second stage produces a second digital value representing the next most significant bits of the digital output. Some two-stage CTP ADC circuitry includes first stage circuitry, second stage circuitry, and output combination circuitry.

The first stage circuitry includes a first sub-ADC circuitry that generates a first digital value representing the most significant bits of the digital output. The first sub-ADC circuitry performs a relatively low precision analog-to-digital conversion. Performing low precision conversions increases the speed and decreases complexity of the first stage circuitry. However, the first digital value has a low-resolution (e.g., a small number of bits) in comparison to the desired resolution of the CTP ADC circuitry due to the relatively low precision of the first sub-ADC.

The second stage circuitry includes delay circuitry, DAC circuitry, combination circuitry, analog filter circuitry, digital filter circuitry, a switch, and second sub-ADC circuitry. The DAC circuitry converts the first digital value from the first stage circuitry into a low-resolution analog value. Such a low-resolution representation of the analog value may be referred to as an approximated analog value. The delay circuitry delays the propagation of the analog input by a duration of time to account for delays in the conversions of the first sub-ADC circuitry and the DAC circuitry. The combination circuitry subtracts the approximated analog value from the delayed analog value to produce a residue voltage representing portions of the delayed analog value that the first stage circuitry could not represent with the relatively low precision of the first sub-ADC circuitry.

The analog filter circuitry amplifies the residue by a frequency dependent gain to increase the magnitudes of high precision portions of the analog residue. The digital filter circuitry amplifies the first digital value by the frequency dependent gain of the analog filter circuitry. The digital filter circuitry compensates the first digital value for the change in resolution resulting from the frequency dependent gain of the analog filter circuitry. However, implementing a frequency dependent gain in digital increases the integration complexity of the CTP ADC circuitry. Also, the digital filter circuitry cannot accurately account for the accumulation of charge in the analog filter circuitry, which further reduces the accuracy of the CTP ADC circuitry.

The switch samples the amplified residue for the second sub-ADC circuitry based on a clock signal. The second sub-ADC circuitry performs another relatively low precision analog-to-digital conversion to produce a second digital value. The second digital value has a low-resolution (e.g., a small number of bits) in comparison to the desired resolution of the CT pipeline ADC circuitry.

Finally, the output combination circuitry combines the filtered first digital value from the digital filter circuitry with the second digital value from the second sub-ADC circuitry. The combined digital value represents the digital output and as a resolution greater than the resolution of both digital values from the sub-ADC circuitry. Although the CTP ADC circuitry produces a relatively high-resolution digital output, the noise, jitter, and frequency dependency of the filter circuitry limits the range of operating frequencies.

Examples described herein include methods and apparatus to perform analog-to-digital conversions in a continuous time pipeline. In some described examples, CTP ADC circuitry includes a first switch, a first ADC, a DAC, first combination circuitry, residue amplifier circuitry, a second switch, a second ADC, and second combination circuitry. The first switch couples the first ADC to an analog input based on a first clock signal. The first ADC generates a first digital value using a relatively low precision analog-to-digital conversion. The DAC generates an approximated analog input by converting the first digital value to analog. The first combination circuitry produces a residue by subtracting the approximation of the analog input from the actual value of the analog input. The residue represents the difference between the analog input and the approximated analog input, which corresponds to the first digital value.

In such described examples, the residue amplifier circuitry amplifies the residue by a fixed gain. In some examples, the gain of the residue amplifier circuitry is proportional to the resolution of the first digital value. For example, the gain is proportional to the number of bits of the first digital value. The second switch couples the second ADC to the amplified input based on a second clock signal. The first and second clock signals are structured to be non-overlapping pulses, such that both switches are not closed at the same time or switch at the same time. The second ADC generates a second digital value responsive to the amplified residue from the second switch. The second combination circuitry generates the digital output of the CTP ADC circuitry by combining the second digital value with a multiplication of the first digital value by the gain of the residue amplifier circuitry.

Advantageously, the CTP ADC circuitry generates a digital output using residue amplifier circuitry operating in continuous time and having a fixed gain, which reduces frequency constraints on the clock signals. Advantageously, using the first and second switches to sample at different times reduces time reduces jitter and improves noise immunity. Advantageously, the CTP ADC circuitry operates independent of the timing of the DAC, which reduces the sensitivity of the CTP ADC circuitry to clock jitter.

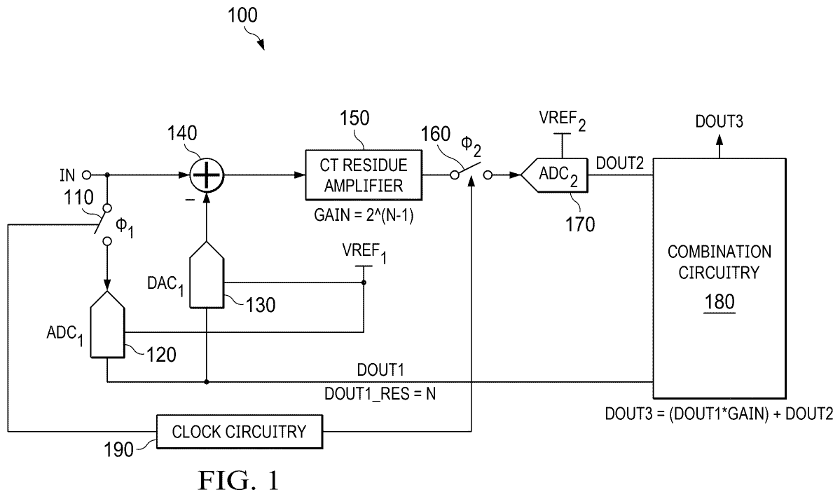

FIG. 1 is a schematic diagram of example CTP ADC circuitry 100. In the example of FIG. 1, the CTP ADC circuitry 100 includes first switch circuitry 110, a first ADC 120, a DAC 130, first combination circuitry 140, residue amplifier circuitry 150, second switch circuitry 160, a second ADC 170, second combination circuitry 180, and clock circuitry 190. The CTP ADC circuitry 100 has an input and an output. The input of the CTP ADC circuitry 100 is structured to be coupled to an analog signal source, which supplies an analog input (IN). The output of the CTP ADC circuitry 100 is structured to be coupled to digital circuitry, which receives digital representations of the analog input signal. For example, in voltage measurement systems, the input of the CTP ADC circuitry 100 is coupled to a node of an integrated circuit and the output of CTP ADC circuitry 100 is coupled to programmable circuitry. In such examples, the programmable circuitry receives digital values representing the analog value of the voltage at the node from the CTP ADC circuitry 100.

The switch circuitry 110 has a first terminal, a second terminal, and a control terminal. The first terminal of the switch circuitry 110 is coupled to the combination circuitry 140 and the input of the CTP ADC circuitry 100, which supplies the analog input. The second terminal of the switch circuitry 110 is coupled to the ADC 120. The control terminal of the switch circuitry 110 is coupled to the clock circuitry 190, which supplies a first clock signal (Ø1). In the example of FIG. 1, the switch circuitry 110 is illustrated and described as a switch. Alternatively, the switch circuitry 110 may be implemented using transistors or with alternative circuitry.

The ADC 120 has a first input, a second input, and an output. The first input of the ADC 120 is coupled to the switch circuitry 110. The second input of the ADC 120 is coupled to the DAC 130 and a first reference terminal, which supplies a first reference voltage (VREF1) from a power supply. In some examples, the first reference voltage represents a range of voltages that the ADC 120 may accurately represent with a digital value. The output of the ADC 120 is coupled to the DAC 130 and the combination circuitry 180.

The DAC 130 has a first input, a second input, and an output. The first input of the DAC 130 is coupled to the ADC 120 and the combination circuitry 180. The second input of the DAC 130 is coupled to the ADC 120 and the first reference terminal, which supplies the first reference voltage (VREF1) from a power supply. In some examples, the first reference voltage represents a range of digital values that the DAC 130 may accurately represent with an analog value. The output of the DAC 130 is coupled to the combination circuitry 140.

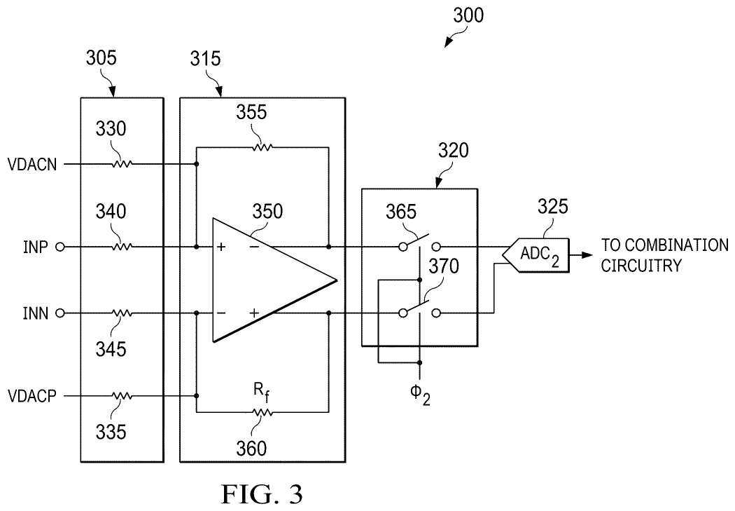

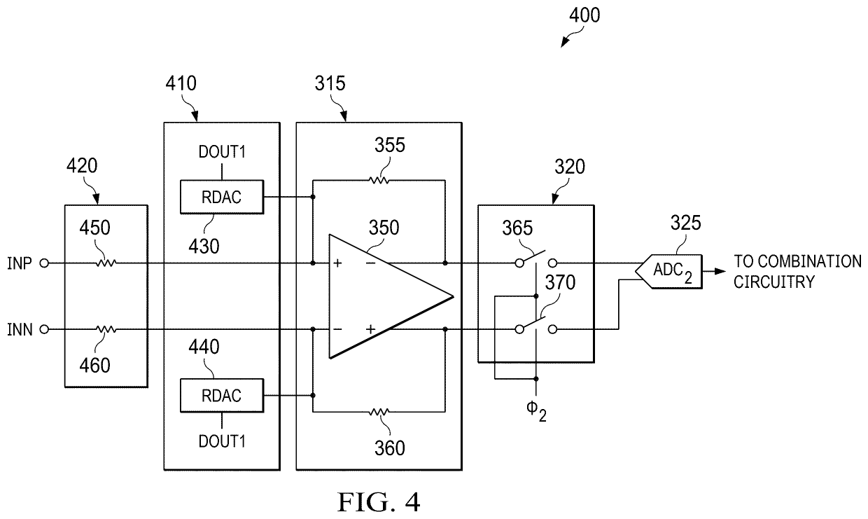

The combination circuitry 140 has a first input, a second input, and an output. The first input of the combination circuitry 140 is coupled to the switch circuitry 110 and the input of the CTP ADC circuitry 100. The second input of the combination circuitry 140 is coupled to the DAC 130. The output of the combination circuitry 140 is coupled to the residue amplifier circuitry 150. In the example of FIG. 1, the combination circuitry 140 is structured as subtraction circuitry. Examples of the combination circuitry 140 are illustrated and described in connection with FIGS. 3 and 4, below.

The residue amplifier circuitry 150 has a first terminal and a second terminal. The first terminal of the residue amplifier circuitry 150 is coupled to the combination circuitry 140. The second terminal of the residue amplifier circuitry 150 is coupled to the switch circuitry 160. An example of the residue amplifier circuitry 150 is illustrated and described in connection with FIGS. 3 and 4, below.

The switch circuitry 160 has a first terminal, a second terminal, and a control terminal. The first terminal of the switch circuitry 160 is coupled to the residue amplifier circuitry 150. The second terminal of the switch circuitry 160 is coupled to the ADC 170. The control terminal of the switch circuitry 160 is coupled to the clock circuitry 190, which supplies a second clock signal (2). In the example of FIG. 1, the switch circuitry 160 is illustrated and described as a switch. Alternatively, the switch circuitry 160 may be implemented using transistors or with alternative circuitry. An example of the switch circuitry 160 is illustrated and described in connection with FIGS. 3 and 4 below.

The ADC 170 has a first input, a second input, and an output. The first input of the ADC 170 is coupled to the switch circuitry 160. The second input of the ADC 170 is coupled to a second reference terminal, which supplies a second reference voltage (VREF2) from a power supply. The output of ADC 170 is coupled to the combination circuitry 180. An example of the ADC 170 is illustrated and described in connection with FIGS. 3 and 4, below.

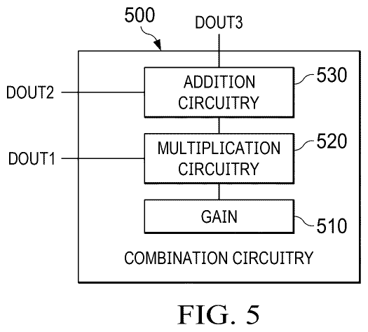

The combination circuitry 180 has a first input, a second input, and an output. The first input of the combination circuitry 180 is coupled to the ADC 120 and the DAC 130. The second input of the combination circuitry 180 is coupled to the ADC 170. The output of the combination circuitry 180 is coupled to the output of the CTP ADC circuitry 100. An example of the combination circuitry 180 is illustrated and described in connection with FIG. 5, below.

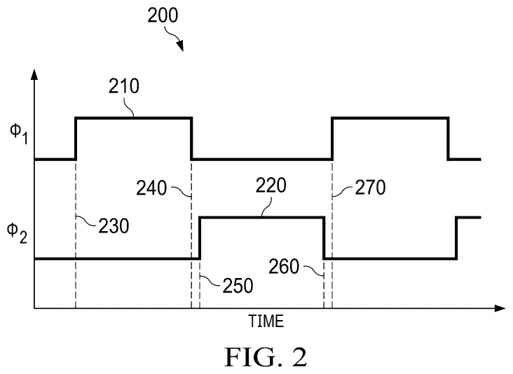

The clock circuitry 190 has a first output and a second output. The first output of the clock circuitry 190 is coupled to the switch circuitry 110. The second output of the clock circuitry 190 is coupled to the switch circuitry 160. Example clock signals of the clock circuitry 190 are illustrated and described in connection with FIG. 2.

FIG. 2 is a timing diagram 200 of example operations of the clock circuitry 190 of FIG. 1. In the example of FIG. 2, the timing diagram 200 includes a first example clock signal 210 (Φ₁) and a second example clock signal 220 (Φ₂). The clock signal 210 represents the control of the switch circuitry 110 of FIG. 1. The switch circuitry 110 closes responsive to rising edges of the clock signal 210. The switch circuitry 110 opens responsive to falling edges of the clock signal 210. The clock signal 220 represents the control of the switch circuitry 160 of FIG. 1. The switch circuitry 160 closes responsive to rising edges of the clock signal 220. The switch circuitry 160 opens responsive to falling edges of the clock signal 220. In some examples, such as systems using active low circuitry or signals, the operations of the switch circuitry 110, 160 may be inversely related to the clock signals 210, 220.

At a first time 230, the switch circuitry 110 closes responsive to a rising edge of the clock signal 210. At the first time 230, the switch circuitry 160 is open responsive to the clock signal 220 being a logic low. At a second time 240, the switch circuitry 110 opens responsive to a falling edge of the clock signal 210. At the second time 240, the switch circuitry 160 remains open responsive to the clock signal 220 being a logic low. Between the times 230, 240, the ADC 120 of FIG. 2 determines a first digital value (DOUT1) and the DAC 130 converts the first digital value to generate an analog approximation.

At a third time 250, the switch circuitry 160 closes responsive to a rising edge of the clock signal 220. At the third time 250, the switch circuitry 110 remains open responsive to the clock signal 210 being a logic low. At a fourth time 260, the switch circuitry 160 opens responsive to a rising edge of the clock signal 220. At the fourth time 260, the switch circuitry 110 remains open responsive to the clock signal 210 being a logic low. Between the times 250, 260, the ADC 170 of FIG. 1 generates a second digital value (DOUT2) by converting an amplified residue from the residue amplifier circuitry 150 of FIG. 1 to digital. Also, between the times 250, 260 and after the ADC 170 generates the second digital value, the combination circuitry 180 of FIG. 1 combines the first and second digital values based on the gain of the residue amplifier circuitry 150 to set the digital output of the CTP ADC circuitry 100. At a fifth time 270, the switch circuitry 110 closes responsive to a rising edge of the clock signal 210. At the fifth time 270, the switch circuitry 160 remains open responsive to the clock signal 220 being a logic low.

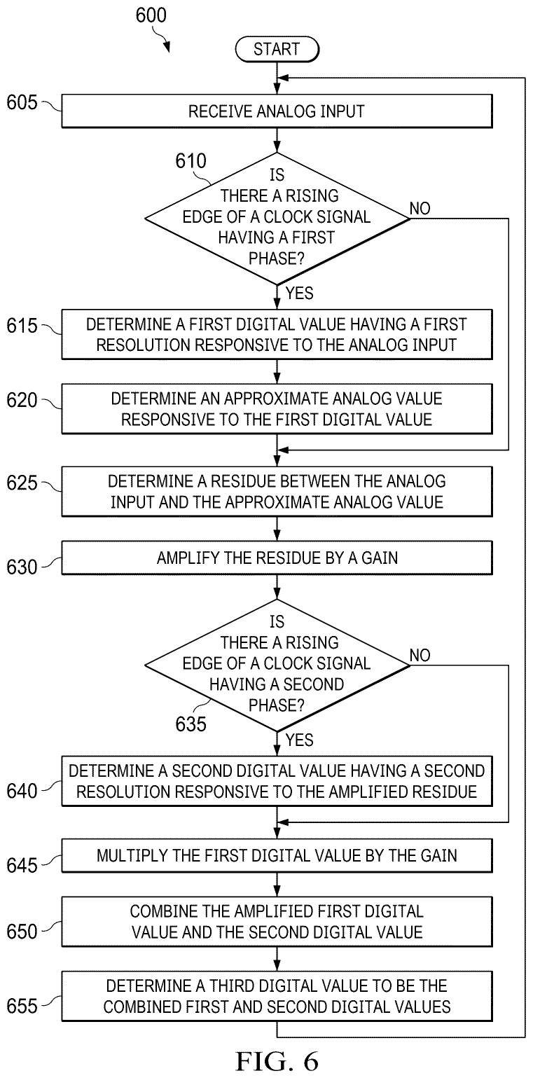

In the example operations, the clock signals 210, 220 are structured to have non-overlapping edges. For example, the rising edge of the clock signal 220 at the time 250 occurs after the falling edge of the clock signal 210 at the time 240. Similarly, the rising edge of the clock signal 210 at the time 270 occurs after the falling edge of the clock signal 220 at the time 260. Such non-overlapping edges of the clock signals 210, 220 reduce the noise resulting from the switching operations of the switch circuitry 110, 160. Example operations of the CTP ADC circuitry 100 in relation to the clock signals 210, 220 are further illustrated and described in connection with FIG. 6, below.

FIG. 3 is a schematic diagram of example second stage circuitry 300 of a differential example of the CTP ADC circuitry 100 of FIG. 1. The second stage circuitry 300 of FIG. 3 corresponds to the operations to determine the second digital value using the DAC 130 of FIG. 1, the combination circuitry 140 of FIG. 1, the residue amplifier circuitry 150 of FIG. 1, the switch circuitry 160 of FIG. 1, and the ADC 170 of FIG. 1. In the example of FIG. 3, the second stage circuitry 300 includes example combination circuitry 305, example residue amplifier circuitry 315, example switch circuitry 320, and an example ADC 325. The example combination circuitry 305 of FIG. 3 includes a first example resistor 330, a second example resistor 335, a third example resistor 340, and a fourth example resistor 345. The example residue amplifier circuitry 315 of FIG. 3 includes an example amplifier 350, a first example resistor 355, and a second example resistor 360. The example switch circuitry 320 of FIG. 3 includes a first example switch 365 and a second example switch 370. Unlike the CTP ADC circuitry 100 of FIG. 1, the second stage circuitry 300 is structured as a differential system. In a differential structure, values of signals are determined as the difference between plus and minus side signals.

The second stage circuitry 300 has a first input, a second input, a third input, a fourth input, a fifth input, a first output, and a second output. The first and second inputs of the second stage circuitry 300 are structured to be coupled to an analog signal source, which supplies a differential analog input (INP, INN). The third and fourth inputs of the second stage circuitry 300 are structured to be coupled to the DAC 130, which is structured to supply a differential analog approximation input (VDACP, VDACN). In the example of FIG. 3, the differential analog approximation is an analog representation of the digital output from the ADC 120 of FIG. 1. The fifth input of the second stage circuitry 300 is structured to be coupled to the clock circuitry 190 of FIG. 1, which supplies the second clock signal (Φ₂) (e.g., the clock signal 220 of FIG. 2). The first and second outputs of the second stage circuitry 300 are structured to be coupled to the combination circuitry 180 of FIG. 1, which receives a digital output (DOUT2).

The combination circuitry 305 has a first terminal, a second terminal, a third terminal, a fourth terminal, a fifth terminal, and a sixth terminal. The first terminal of the combination circuitry 305 is coupled to the third input of the second stage circuitry 300, which supplies the minus side analog approximation input (VDACN). The second terminal of the combination circuitry 305 is coupled to the fourth input of the second stage circuitry 300, which supplies the plus side analog approximation input (VDACP). The third terminal of the combination circuitry 305 is coupled to the first input of the second stage circuitry 300, which supplies the plus side analog input (INP). The fourth terminal of the combination circuitry 305 is coupled to the second input of the second stage circuitry 300, which supplies the minus side analog input (INN). The fifth and sixth terminals of the combination circuitry 305 are coupled to the residue amplifier circuitry 315. The combination circuitry 305 is a differential example of the combination circuitry 140 of FIG. 1.

The residue amplifier circuitry 315 has a first terminal, a second terminal, a third terminal, and a fourth terminal. The first and second terminals of the residue amplifier circuitry 315 are coupled to the combination circuitry 305. The third and fourth terminals of the residue amplifier circuitry 315 are coupled to the switch circuitry 320. The residue amplifier circuitry 315 is a differential example of the residue amplifier circuitry 150 of FIG. 1.

The switch circuitry 320 has a first terminal, a second terminal, a third terminal, a fourth terminal, and a control terminal. The first and second terminals of the switch circuitry 320 are coupled to the residue amplifier circuitry 315. The third and fourth terminals of the switch circuitry 320 are coupled to the ADC 325. The control terminal of the switch circuitry 320 is coupled to the fifth input of the second stage circuitry 300, which supplies the clock signal 220. The switch circuitry 320 is a differential example of the switch circuitry 160 of FIG. 1.

The ADC 325 has a first terminal, a second terminal, a third terminal, and a fourth terminal. The first and second terminals of the ADC 325 are coupled to the switch circuitry 320. The third and fourth terminals of the ADC 325 are coupled to the first and second outputs of the second stage circuitry 300. The ADC 325 is a differential example of the ADC 170 of FIG. 1.

The resistor 330 has a first terminal and a second terminal. The first terminal of the resistor 330 is coupled to the third input of the second stage circuitry 300, which supplies the minus side analog approximation input (VDACN). The second terminal of the resistor 330 is coupled to the resistors 340, 355 and the amplifier 350.

The resistor 335 has a first terminal and a second terminal. The first terminal of the resistor 335 is coupled to the fourth input of the second stage circuitry 300, which supplies the plus side analog approximation input (VDACP). The second terminal of the resistor 335 is coupled to the resistors 345, 360 and the amplifier 350.

The resistor 340 has a first terminal and a second terminal. The first terminal of the resistor 340 is coupled to the first input of the second stage circuitry 300, which supplies the plus side analog input (INP). The second terminal of the resistor 340 is coupled to the resistors 330, 355 and the amplifier 350.

The resistor 345 has a first terminal and a second terminal. The first terminal of the resistor 345 is coupled to the second input of second stage circuitry 300, which supplies the minus side analog input (INN). The second terminal of the resistor 345 is coupled to the resistors 335, 360 and the amplifier 350.

The amplifier 350 has a non-inverting input, an inverting input, an inverting output, and a non-inverting output. The non-inverting input of the amplifier 350 is coupled to the resistors 330, 340, 355. The inverting input of the amplifier 350 is coupled to the resistors 335, 345, 360. The inverting output of the amplifier 350 is coupled to the resistor 355 and the switch 365. The non-inverting output of the amplifier 350 is coupled to the resistor 360 and the switch 370.

The resistor 355 has a first terminal and a second terminal. The first terminal of the resistor 355 is coupled to the resistors 330, 340 and the amplifier 350. The second terminal of the resistor 355 is coupled to the amplifier 350 and the switch 365.

The resistor 360 has a first terminal and a second terminal. The first terminal of the resistor 360 is coupled to the resistors 335, 345 and the amplifier 350. The second terminal of the resistor 360 is coupled to the amplifier 350 and the switch 370.

The switch 365 has a first terminal, a second terminal, and a control terminal. The first terminal of the switch 365 is coupled to the amplifier 350 and the resistor 355. The second terminal of the switch 365 is coupled to the ADC 325. The control terminal of the switch 365 is coupled to the switch 370 and the fifth input of the second stage circuitry 300, which supplies the clock signal 220.

The switch 370 has a first terminal, a second terminal, and a control terminal. The first terminal of the switch 370 is coupled to the amplifier 350 and the resistor 360. The second terminal of the switch 370 is coupled to the ADC 325. The control terminal of the switch 370 is coupled to the switch 365 and the fifth input of the second stage circuitry 300, which supplies the clock signal 220.

Advantageously, the residue amplifier circuitry 315 uses the resistors 355, 360 to implement a fixed gain, which reduces timing constraints. Advantageously, the resistors 330, 335, 340, 345 are structured to subtract currents of the output of the DAC 130 from currents proportional to the analog input. Example operations of the second stage circuitry 300 of FIG. 3 are illustrated and described in connection with FIG. 6, below.

FIG. 4 is a schematic diagram of example second stage circuitry 400 of a differential example of the CTP ADC circuitry 100 of FIG. 1, which is another example of the second stage circuitry 300 of FIG. 3. Similar to the second stage circuitry 300 of FIG. 3, the second stage circuitry 400 corresponds to the operations to determine the second digital value using the DAC 130 of FIG. 1, the combination circuitry 140 of FIG. 1, the residue amplifier circuitry 150 of FIG. 1, the switch circuitry 160 of FIG. 1, and the ADC 170 of FIG. 1. In the example of FIG. 4, the second stage circuitry 400 includes the residue amplifier circuitry 315 of FIG. 3, the switch circuitry 320 of FIG. 3, the ADC 325 of FIG. 3, example DAC circuitry 410, and example combination circuitry 420. The example residue amplifier circuitry 315 of FIG. 4 includes the amplifier 350 of FIG. 3 and the resistors 355, 360 of FIG. 3. The example switch circuitry 320 of FIG. 4 includes the switches 365, 370 of FIG. 3. The example DAC circuitry 410 of FIG. 4 includes a first resistor DAC (RDAC) 430 and a second example RDAC 440. The example combination circuitry 420 of FIG. 4 includes a first example resistor 450 and a second example resistor 460. The second stage circuitry 400 is structured as a differential system. In a differential structure, values of signals are determined as the difference between plus and minus side signals.

The second stage circuitry 400 has a first input, a second input, a third input, a fourth input, a first output, and a second output. The first and second inputs of the second stage circuitry 400 are structured to be coupled to an analog signal source, which supplies a differential analog input (INP, INN). The third input of the second stage circuitry 400 is structured to be coupled to the ADC 120, which is structured to supply a first digital value (DOUT1). In the example of FIG. 4, the first digital value is a relatively low-resolution output of the ADC 120 of FIG. 1. The fourth input of the second stage circuitry 400 is structured to be coupled to the clock circuitry 190 of FIG. 1, which supplies the second clock signal (Ø2) (e.g., the clock signal 220 of FIG. 2). The first and second outputs of the second stage circuitry 400 are structured to be coupled to the combination circuitry 180 of FIG. 1, which receives a second digital value (DOUT2).

The DAC circuitry 410 has a first terminal, a second terminal, and a third terminal. The first terminal of the DAC circuitry 410 is coupled to the third input of the second stage circuitry 400, which supplies the first digital value (DOUT1). The second and third terminals of the DAC circuitry 410 are coupled to the residue amplifier circuitry 315 and the combination circuitry 420.

The combination circuitry 420 has a first terminal, a second terminal, a third terminal, and a fourth terminal. The first terminal of the combination circuitry 420 is coupled to the first input of the second stage circuitry 400, which supplies the plus side analog input (INP). The second terminal of the combination circuitry 420 is coupled to the second input of the second stage circuitry 400, which supplies the minus side analog input (INN). The third and fourth terminals of the combination circuitry 420 are coupled to the residue amplifier circuitry 315 and the DAC circuitry 410.

The RDAC 430 has an input and an output. The input of the RDAC 430 is coupled to the RDAC 440 and the third input of the second stage circuitry 400, which supplies the first digital value (DOUT1). The output of the RDAC 430 is coupled to the amplifier 350 and the resistors 355, 450.

The RDAC 440 has an input and an output. The input of the RDAC 440 is coupled to the RDAC 430 and the third input of the second stage circuitry 400, which supplies the first digital value (DOUT1). The output of the RDAC 440 is coupled to the amplifier 350 and the resistors 360, 460.

The resistor 450 has a first terminal and a second terminal. The first terminal of the resistor 450 is coupled to the first input of the second stage circuitry 400, which supplies the plus side analog input (INP). The second terminal of the resistor 450 is coupled to the amplifier 350, the resistor 355, and the RDAC 430.

The resistor 460 has a first terminal and a second terminal. The first terminal of the resistor 460 is coupled to the second input of the second stage circuitry 400, which supplies the minus side analog input (INN). The second terminal of the resistor 460 is coupled to the amplifier 350, the resistor 360, and the RDAC 440.

Advantageously, the RDACs 430, 440 and the resistors 450, 460 are structured to subtract currents of the output of the DAC 130 from currents proportional to the analog input. Example operations of the second stage circuitry 400 of FIG. 4 are illustrated and described in connection with FIG. 6, below.

FIG. 5 is a block diagram of example combination circuitry 500, which is an example of the combination circuitry 180 of FIG. 1. In the example of FIG. 5, the combination circuitry 500 includes a gain value circuitry 510, multiplication circuitry 520, and addition circuitry 530. The combination circuitry 500 of FIG. 5 has a first input, a second input, and an output. The first input of the combination circuitry 500 is structured to be coupled to the ADC 120 of FIG. 1, which supplies a first digital value (DOUT1). The second input of the combination circuitry 500 is structured to be coupled to the ADC 170 of FIG. 1, which supplies a second digital value (DOUT2). The output of the combination circuitry 500 supplies a third digital value (DOUT3).

The gain value circuitry 510 has a terminal coupled to the multiplication circuitry 520. In some examples, the gain value circuitry 510 is a storage component, such as a register, portion of memory, etc. In such examples, the gain value circuitry 510 stores a value representing the gain of the residue amplifier circuitry 150, 315 of FIGS. 1, 3 and 4. In other examples, the gain value circuitry 510 includes circuitry to determine the gain of the residue amplifier circuitry 150, 315. For example, the gain value circuitry 510 determines the gain of the residue amplifier circuitry 150, 315 based on the resolution (e.g., number of bits) of the first digital output from the ADC 120 of FIG. 1. In such examples, the gain of the residue amplifier circuitry 150, 315 is proportional to the resolution of the first digital output. Such an example is further described in connection with FIG. 6, below.

The multiplication circuitry 520 has a first input, a second input, and an output. The first input of the multiplication circuitry 520 is coupled to the first input of the combination circuitry 500, which supplies the first digital value (DOUT1). The second input of the multiplication circuitry 520 is coupled to the gain value circuitry 510. The output of the multiplication circuitry 520 is coupled to the addition circuitry 530.

The addition circuitry 530 has a first input, a second input, and an output. The first input of the addition circuitry 530 is coupled to the second input of the combination circuitry 500, which supplies the second digital value (DOUT2). The second input of the addition circuitry 530 is coupled to the multiplication circuitry 520. The output of the addition circuitry 530 is coupled to the output of the combination circuitry 500.

Advantageously, the combination circuitry 500 combines the first and second digital values from the ADCs 120, 170 using multiplication and addition. Advantageously, using the fixed gain in the residue amplifier circuitry 150, 315 reduces the complexity of the combination circuitry 180, 500. Example operations of the combination circuitry 180, 500 are further illustrated and described in connection with FIG. 6, below.

FIG. 6 is a flowchart representative of example machine-readable instructions or example operations 600 that may be at least one of executed, instantiated, or performed using an example implementation of the second stage circuitry 300, 400 of FIGS. 3 and 4, the combination circuitry 500 of FIG. 5, or more generally the CTP ADC circuitry 100 of FIG. 1. The example operations 600 of FIG. 6 begin at Block 605 at which the CTP ADC circuitry 100 receives an analog input. In some examples, external circuitry supplies an analog input (IN) to the CTP ADC circuitry 100. In some such examples, such as in FIGS. 3 and 4, the CTP ADC circuitry 100 is structured to receive a differential analog input.

The switch circuitry 110 of FIG. 1 determines if there is a rising edge of a clock signal having a first phase. (Block 610). In example operations, the clock signal 210 of FIG. 2 from the clock circuitry 190 of FIG. 1 controls the switch circuitry 110. In such example operations, the switch circuitry 110 closes responsive to rising edges of the clock signal 210. For example, the rising edge of the clock signal 210 at the time 230 of FIG. 2 closes the switch circuitry 110. Similarly, the switch circuitry 110 opens responsive to falling edges of the clock signal 210. For example, the falling edge of the clock signal 210 at the time 240 of FIG. 2 closes the switch circuitry 110.

If the switch circuitry 110 determines that there is a rising edge of the clock signal having the first phase (e.g., Block 610 returns a result of YES), the ADC 120 of FIG. 1 determines a first digital value having a first resolution responsive to the analog input. (Block 615). In example operations, the ADC 120 receives the analog input of the CTP ADC circuitry 100 responsive to the clock signal 210 closing the switch circuitry 110. In such example operations, the ADC 120 produces a first digital value (DOUT1) responsive to receiving the analog input from the switch circuitry 110. In some examples, the precision of the ADC 120 determines the resolution of the first digital value. In such examples, the ADC 120 has a relatively low precision in comparison to the output of the CTP ADC circuitry 100. Advantageously, reducing the precision of the ADC 120 increases the speed of the analog-to-digital conversion. Advantageously, reducing the precision of the ADC 120 reduces the integration complexity of the ADC 120. For example, relatively low-resolution ADCs can be implemented using relatively high-speed flash circuitry, a series of comparators, etc.

The DAC 130 of FIG. 1 determines an approximate analog value responsive to the first digital value. (Block 620). In example operations, the DAC 130 converts the first digital value from the ADC 120 to generate an approximate analog value. The approximate analog value represents an analog input of the relatively low-resolution analog-to-digital conversion of the ADC 120. In such example operations, the approximate analog value is an analog representation of the first digital value from the ADC 120.

If the switch circuitry 110 determines that there is not a rising edge of the clock signal having the first phase (e.g., Block 610 returns a result of NO) or control proceeds from Block 620, the combination circuitry 140, 305, 420 of FIGS. 1, 3, and 4 determines a residue between the analog input and the approximate analog value. (Block 625). In example operations, the combination circuitry 140, 305, 420 subtracts the approximate analog value from the DAC 130 from the analog input of the CTP ADC circuitry 100 to determine a residue. In such example operations, the residue represents the difference between the approximate analog value of the first digital value and the actual value of the analog input of the CTP ADC circuitry 100. For example, the resistors 330, 335 of FIG. 3 generate currents proportional to the approximated analog value from the DAC 130 and the resistors 340, 345 of FIG. 3 generate currents proportional to the analog input of the CTP ADC circuitry 100. In such an example, the resistors 330, 340 subtract the current of the minus side approximate analog value from the current of the plus side analog input of the CTP ADC circuitry 100 and the resistors 335, 345 subtract the current of the plus side approximate analog value from the current of the minus side analog input of the CTP ADC circuitry 100. Advantageously, in such examples, the current at the inputs of the residue amplifier circuitry 150, 3151 of FIGS. 1 and 3 are proportional to the difference between the actual value of the analog input and the approximate analog value. In another example, the resistors 450, 460 of FIG. 4 subtract currents of the analog input of the CTP ADC circuitry 100 from the currents of the RDACs 430, 440 of FIG. 4 to produce the residue. Advantageously, the residue represents the portions of the analog input of the CTP ADC circuitry 100 that the ADC 120 cannot represent with the first digital value.

The residue amplifier circuitry 150, 315 of FIGS. 1 and 3 amplifies the residue by a gain. (Block 630). In example operations, the residue amplifier circuitry 150, 315 is structured to amplify the residue from the combination circuitry 140, 305, 420 by a gain. In some examples, the gain is proportional to the number of bits forming the resolution of the first digital value. For example, when the first digital value has a resolution (DOUT1_RES) equal to a reference number of bits (N), the residue amplifier circuitry 150, 315 has a gain (GAIN) of two to the power of the reference number of bits minus one. Such an example determination of the gain is illustrated in Equation (1), below.

$$GAIN = {2}^{N - 1} \qquad Equation ( 1 )$$

In such examples, one or more of the resistors 330, 335, 340, 345, 355, 360, 450, 460 of FIGS. 3 and 4 are sized to implement the determined gain. For example, the ratio of the resistances of the resistors 355, 340 are set to implement the gain. In another example the ratio of the resistances of the resistors 355, 450 are set to implement the gain. Advantageously, amplifying the residue decreases the complexity in determining digital values of the remaining portions of the analog input responsive to increasing the magnitudes of portions of the analog input that the ADC 120 cannot determine.

The switch circuitry 160, 320 of FIGS. 1 and 3 determines if there is a rising edge of a clock signal having a second phase. (Block 635). In example operations, the clock signal 220 of FIG. 2 from the clock circuitry 190 controls the switch circuitry 160. In such example operations, the switch circuitry 160 closes responsive to rising edges of the clock signal 220. For example, the rising edge of the clock signal 220 at the time 250 of FIG. 2 closes the switch circuitry 160. Similarly, the switch circuitry 160 opens responsive to falling edges of the clock signal 220. For example, the falling edge of the clock signal 220 at the time 260 of FIG. 2 closes the switch circuitry 160.

If the switch circuitry 160, 320 determines there is a rising edge of the clock signal having the second phase (e.g., Block 635 returns a result of YES), the ADC 170, 325 of FIGS. 1 and 3 determines a second digital value having a second resolution responsive to the amplifier residue. (Block 640). In example operations, the ADC 170, 325 receives the amplified residue responsive to the clock signal 220 closing the switch circuitry 160. In such example operations, the ADC 170 produces a second digital value (DOUT2) responsive to receiving the analog input from the switch circuitry 160. In some examples, the precision of the ADC 170 determines the resolution of the second digital value. In such examples, the ADC 170 has a relatively low precision in comparison to the output of the CTP ADC circuitry 100. Advantageously, reducing the precision of the ADC 170 increases the speed of the analog-to-digital conversion. Advantageously, reducing the precision of the ADC 170 reduces the integration complexity of the ADC 170. For example, relatively low-resolution ADCs can be implemented using relatively high-speed flash circuitry, a series of comparators, etc.

If the switch circuitry 160, 320 determines there is not a rising edge of the clock signal having the second phase (e.g., Block 635 returns a result of NO) or control proceed from Block 640, the combination circuitry 180, 500 of FIGS. 1 and 5 multiplies the first digital value by the gain. (Block 645). In example operations, the combination circuitry 180, 500 receives the first digital value (DOUT1) from the ADC 120 and the gain value from the gain value circuitry 510 of FIG. 5. In some examples, the gain value circuitry 510 determines the gain responsive to the resolution of the first digital value and using Equation (1), above. In such example operations, the multiplication circuitry 520 of FIG. 5 multiplies the first digital value by the determined gain to produce a compensated digital value (DOUT1_{COMP}). Such a multiplication is illustrated in Equation (2), below. Advantageously, multiplying the first digital value by the gain compensates the first digital value for change in resolution resulting from amplifying the residue.

$$DOUT {1}_{COMP} = DOUT 1 * GAIN \qquad Equation ( 2 )$$

The combination circuitry 180, 500 combines the amplified first digital value and the second digital value. (Block 650). In example operations, the combination circuitry 180, 500 receives the second digital value (DOUT2) from the ADC 170 and the compensated digital value from the multiplication circuitry 520. In such example operations, the addition circuitry 530 of FIG. 5 adds the compensated digital value and the second digital value to produce a third digital value (DOUT3). Such an addition is illustrated in Equation (3), below. Advantageously, adding the compensated digital value and the second digital value produces a digital value having a resolution greater than the resolution of both the first and second digital values.

$$DOUT 3 = DOUT {1}_{COMP} + DOUT 2 \qquad Equation ( 3 )$$

The combination circuitry 180, 500 determines a third digital value to be the combined first and second digital values. (Block 655). In example operations, the combination circuitry 180, 500 supplies the third digital value as the output of the CTP ADC circuitry 100. In such example operations, the third digital value has a resolution approximately equal to the number of bits determined by the ADC 120 plus the number of bits determined by the ADC 170. Advantageously, the CTP ADC circuitry 100 determines a relatively high precision digital value using relatively low precision ADCs, such as the ADCs 120, 170. Control proceeds to return to Block 605.

Example methods are described with reference to the flowchart illustrated in FIG. 6. However, many other methods of implementing the second stage circuitry 300, 400 of FIGS. 3 and 4, the combination circuitry 500 of FIG. 5, or more generally the CTP ADC circuitry 100 of FIG. 1 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

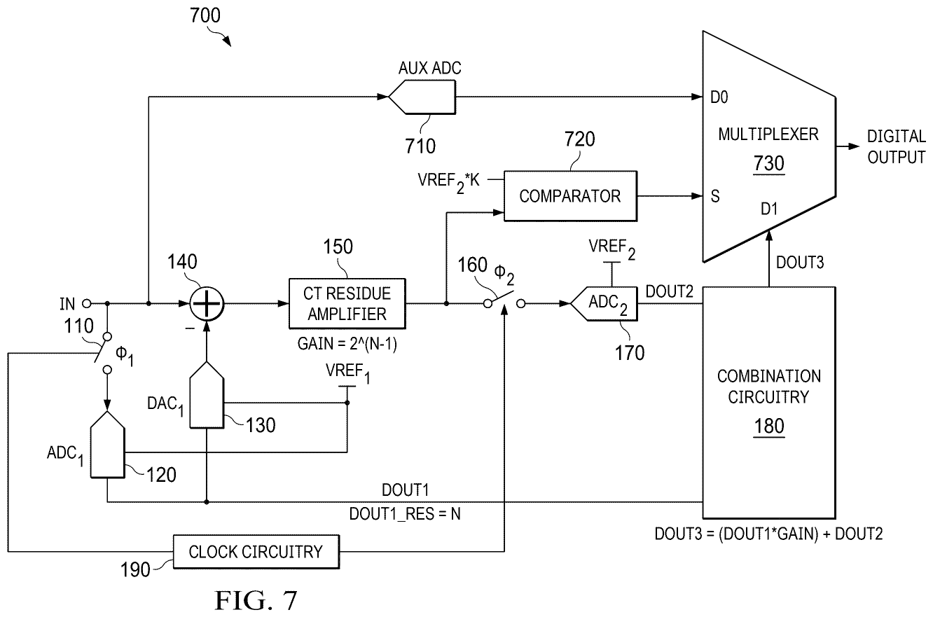

FIG. 7 is a schematic diagram of example dual path CTP ADC circuitry 700 including the CTP ADC circuitry 100 of FIG. 1. In the example of FIG. 7, the dual path CTP ADC circuitry 700 includes the switch circuitry 110, 160 of FIG. 1, the ADCs 120, 170 of FIG. 1, the DAC 130 of FIG. 1, the combination circuitry 140 of FIG. 1, the residue amplifier circuitry 150 of FIG. 1, the combination circuitry 180 of FIG. 1, the clock circuitry 190 of FIG. 1, an auxiliary ADC 710, comparator circuitry 720, and multiplexer circuitry 730.

The dual path CTP ADC circuitry 700 of FIG. 7 has an input and an output. The input of the dual path CTP ADC circuitry 700 is structured to be coupled to an analog signal source, which supplies an analog input (IN). The output of the dual path CTP ADC circuitry 700 is structured to be coupled to digital circuitry structured to receive digital representations of the analog input signal.

The ADC 710 has an input and an output. The input of the ADC 710 is coupled to the switch circuitry 110, the combination circuitry 140, and the input of the dual path CTP ADC circuitry 700. The output of the ADC 710 is coupled to the multiplexer circuitry 730.

The comparator circuitry 720 has a first input, a second input, and an output. The first input of the comparator circuitry 720 is coupled to the residue amplifier circuitry 150 and the switch circuitry 160. The second input of the comparator circuitry 720 is coupled to a threshold voltage, which is structured to be a voltage near the second reference voltage of the ADC 170. In some examples, the dual path CTP ADC circuitry 700 scales the second reference voltage by a scalar (K) to set the threshold voltage of the comparator circuitry 720. For example, the dual path CTP ADC circuitry 700 may include voltage divider circuitry to set the threshold voltage equal to ninety percent of the second reference voltage (VREF2*0.9). In such examples, the threshold voltage represents voltages spanning ninety percent of the range of the ADC 170. The output of the comparator circuitry 720 is coupled to the multiplexer circuitry 730.

The multiplexer circuitry 730 has a first input, a second input, a control terminal, and an output. The first input of the multiplexer circuitry 730 is coupled to the combination circuitry 180. The second input of the multiplexer circuitry 730 is coupled to the ADC 710. The control terminal of the multiplexer circuitry 730 is coupled to the comparator 720. The output of the multiplexer circuitry 730 is coupled to the output of the dual path CTP ADC circuitry 700.

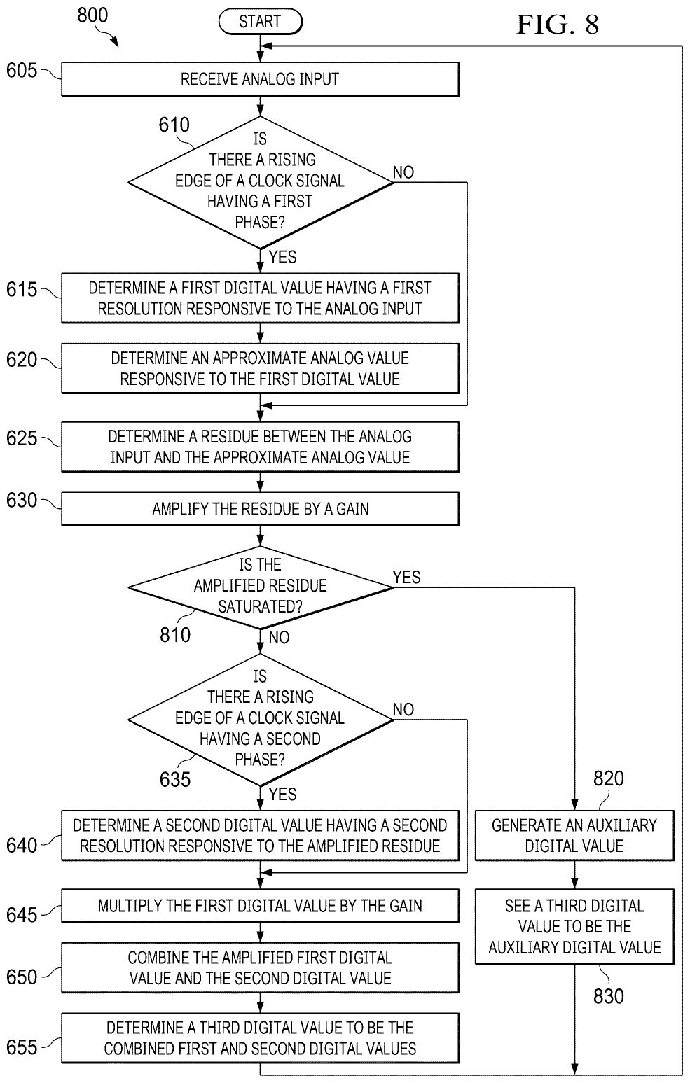

FIG. 8 is a flowchart representative of example machine-readable instructions or example operations 800 that may be at least one of executed, instantiated, or performed using an example implementation of the dual path CTP ADC circuitry of 700 FIG. 7. The example operations 800 of FIG. 8 begin with the operations of Blocks 605, 610, 615, 620, 625, 630 of FIG. 6.

Unlike the example operations 600 of FIG. 6, the control of the operations 800 of FIG. 8 proceeds to Block 810 at which the comparator circuitry 720 of FIG. 7 determines if the amplified residue is saturated. (Block 810). The residue amplifier circuitry 150, 315 of FIGS. 1, 3, and 4 produce a saturated amplified residue responsive to the analog input of the CTP ADC circuitry 700 substantially changing between closing the switch circuitry 110 of FIGS. 1 and 7 and closing the switch circuitry 160 of FIGS. 1 and 7. The residue amplifier circuitry 150, 315 produces an amplified residue approximately equal to the second reference voltage of the ADC 170 when the analog input saturates the residue. The ADCs 170, 325 of FIGS. 1, 3, and 4 produce a maximum digital value responsive to the saturated output of the residue amplifier circuitry 150, 315, which inaccurately represents the value of the analog input. For example, saturation occurs when the analog input of the CTP ADC circuitry 700 changes by a value greater than the second reference voltage (VREF2) of the ADC 170 divided by the gain of the residue amplifier circuitry 150, 315 between the times 240, 260 of FIG. 2. In such examples, the second reference voltage sets the range of analog voltages that the ADC 170 may accurately represent with a digital value. In example operation, when the amplified residue is greater than the second reference voltage of the ADC 170, the second digital output of the ADC 170 is all ones no matter the actual value of the amplified residue.

In example operations, the comparator circuitry 720 compares the amplified residue at the output of the residue amplifier circuitry 150, 315 to the second reference voltage (VREF2) of the ADC 170. In some examples, the comparator circuitry 720 is also structured to compare the amplified residue to another reference voltage of one of the ADCs 120, 170. Advantageously, the comparator circuitry 720 detects saturated outputs of the residue amplifier circuitry 150, 315.

If the comparator circuitry 720 determines that the amplified residue is not saturated (e.g., Block 810 returns a result of NO), control proceeds to Blocks 635, 640, 645, 650, 655 of FIG. 6. In example operations, the comparator circuitry 720 controls the multiplexer circuitry 730 of FIG. 7. In such example operations, the comparator circuitry 720 structures the multiplexer circuitry 730 to set the output of the CTP ADC circuitry 700 to the third digital value from the combination circuitry 180, 500 of FIGS. 1, 5, and 7 responsive to detecting the amplified residue is not saturated.

If the comparator circuitry 720 determines that the amplified residue is saturated (e.g., Block 810 returns a result of YES), the ADC 710 of FIG. 10 generates an auxiliary digital value. (Block 820). In example operations, the ADC 710 samples the analog input of the CTP ADC circuitry 700. In such example operations, the ADC 710 produces an auxiliary digital value (DOUT_{AUX}) responsive to sampling the analog input. Advantageously, unlike the conversions of the ADCs 120, 170, the ADC 710 generates the auxiliary digital value despite relatively high-speed changes in the analog input.

The multiplexer circuitry 730 of FIG. 7 sets a third digital value to be the auxiliary digital value. (Block 830). In example operations, the comparator circuitry 720 structures the multiplexer circuitry 730 to set the output of the CTP ADC circuitry 700 to the auxiliary digital value from the ADC 710 responsive to detecting the amplified residue is saturated. Advantageously, in control systems relying on feedback from the CTP ADC circuitry 700, the ADC 710, the comparator circuitry 720, and the multiplexer circuitry 730 ensure the CTP ADC circuitry 700 supplies an accurate digital output. Control proceeds to return to Block 605.

Example methods are described with reference to the flowchart illustrated in FIG. 8. However, many other methods of implementing the dual path CTP ADC circuitry 700 of FIG. 7 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

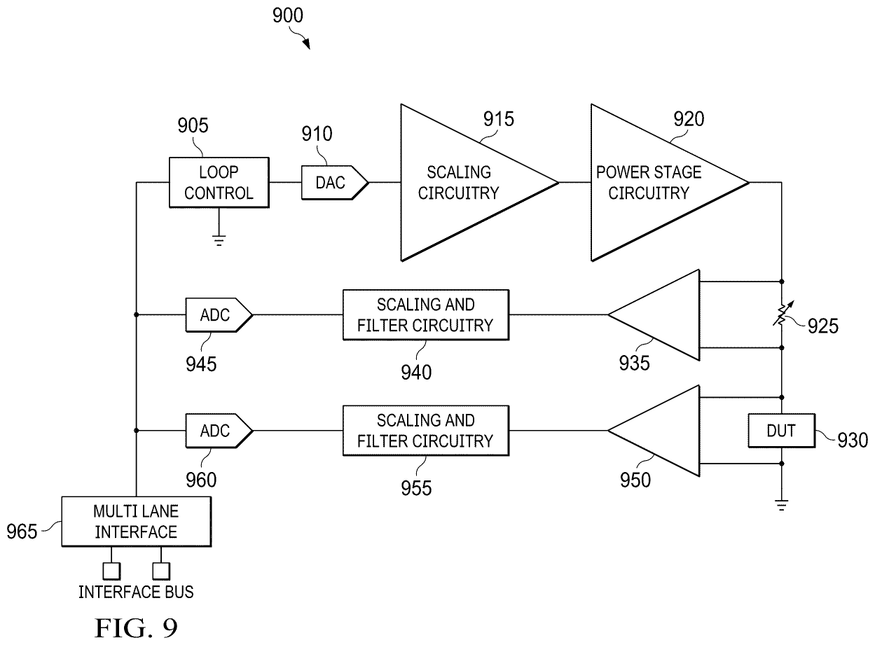

FIG. 9 is a schematic diagram of an example device test system 900. In the example of FIG. 9, the device test system 900 includes loop control circuitry 905, a DAC 910, scaling circuitry 915, power stage circuitry 920, a variable resistor 925, a device under test (DUT) 930, first voltage sense circuitry 935, first scaling and filter circuitry 940, first CTP ADC circuitry 945, second voltage sense circuitry 950, second scaling and filter circuitry 955, second CTP ADC circuitry 960, and interface circuitry 965. The device test system 900 has an input and an output. In some examples, the input and output of the device test system 900 form a multi-lane communication bus, which allows external circuitry to communicate with the device test system 900. In some such examples, the device test system 900 supplies power consumption data to external circuitry using the input and output interface of device test system 900.

The loop control circuitry 905 has a first terminal and a second terminal. The first terminal of the loop control circuitry 905 is coupled to the CTP ADC circuitry 940, 955 and the interface circuitry 965. The second terminal of the loop control circuitry 905 is coupled to the DAC 910. In some examples, the loop control circuitry 905 is referred to as controller circuitry, which is structured to implement a control scheme, such as proportional, integral, and differential (PID) control.

The DAC 910 has an input and an output. The input of the DAC 910 is coupled to the loop control circuitry 905. The output of the DAC 910 is coupled to the scaling circuitry 915.

The scaling circuitry 915 has a first terminal and a second terminal. The first terminal of the scaling circuitry 915 is coupled to the DAC 910. The second terminal of the scaling circuitry 915 is coupled to the power stage circuitry 920.

The power stage circuitry 920 has a first terminal and a second terminal. The first terminal of the power stage circuitry 920 is coupled to the scaling circuitry 915. The second terminal of the power stage circuitry 920 is coupled to the variable resistor 925 and the voltage sense circuitry 935.

The variable resistor 925 has a first terminal and a second terminal. The first terminal of the variable resistor 925 is coupled to the power stage circuitry 920 and the voltage sense circuitry 935. The second terminal of the variable resistor 925 is coupled to the DUT 930 and the voltage sense circuitry 935, 950. In some examples, the variable resistor 925 has a control terminal, which sets the resistance of the resistor 925, coupled to the loop control circuitry 905. In such examples, the control terminal of the variable resistor 925 allows the loop control circuitry 905 to adjust the resistance of the variable resistor 925 to implement different current ranges and improve the total supported current range of the device test system.

The DUT 930 has a first terminal and a second terminal. The first terminal of the DUT 930 is coupled to the variable resistor 925 and the voltage sense circuitry 935, 950. The second terminal of the DUT 930 is coupled to the voltage sense circuitry 950 and the common terminal, which supplies the common potential.

The voltage sense circuitry 935 has a first terminal, a second terminal, and a third terminal. The first terminal of the voltage sense circuitry 935 is coupled to the power stage circuitry 920 and the variable resistor 925. The second terminal of the voltage sense circuitry 935 is coupled to the variable resistor 925, the DUT 930, and the voltage sense circuitry 950. The third terminal of the voltage sense circuitry 935 is coupled to the scaling and filter circuitry 940.

The scaling and filter circuitry 940 has a first terminal and a second terminal. The first terminal of the scaling and filter circuitry 940 is coupled to the voltage sense circuitry 935. The second terminal of the scaling and filter circuitry 940 is coupled to the CTP ADC circuitry 945. In some examples, the scaling and filter circuitry 940 may be illustrated and described as separate components. In the example of FIG. 9, the components that scale also filter voltages from the voltage sense circuitry 935.

The CTP ADC circuitry 945 has an input and an output. The input of the CTP ADC circuitry 945 is coupled to the scaling and filter circuitry 940. The output of the CTP ADC circuitry 945 is coupled to the loop control circuitry 905, the CTP ADC circuitry 960, and the interface circuitry 965. The CTP ADC circuitry 945 is an example implementation of the CTP ADC circuitry 100, 700 of FIGS. 1 and 7.

The voltage sense circuitry 950 has a first terminal, a second terminal, and a third terminal. The first terminal of the voltage sense circuitry 950 is coupled to the variable resistor 925, the DUT 930, and the voltage sense circuitry 935. The second terminal of the voltage sense circuitry 950 is coupled to the DUT 930 and the common terminal, which supplies the common potential. The third terminal of the voltage sense circuitry 950 is coupled to the scaling and filter circuitry 955.

The scaling and filter circuitry 955 has a first terminal and a second terminal. The first terminal of the scaling and filter circuitry 955 is coupled to the voltage sense circuitry 950. The second terminal of the scaling and filter circuitry 955 is coupled to the CTP ADC circuitry 960. In some examples, the scaling and filter circuitry 955 may be illustrated and described as separate components. In the example of FIG. 9, the components that scale also filter voltages from the voltage sense circuitry 950.

The CTP ADC circuitry 960 has an input and an output. The input of the CTP ADC circuitry 960 is coupled to the scaling and filter circuitry 955. The output of the CTP ADC circuitry 960 is coupled to the loop control circuitry 905, the CTP ADC circuitry 945, and the interface circuitry 965. The CTP ADC circuitry 960 is an example implementation of the CTP ADC circuitry 100, 700 of FIGS. 1 and 7.

The interface circuitry 965 has a first terminal, a second terminal, and a third terminal. The first terminal of the interface circuitry 965 is coupled to the CTP ADC circuitry 945, 960. The second terminal of the interface circuitry 965 is coupled to the input of the device test system 900. The third terminal of the interface circuitry 965 is coupled to the output of the device test system 900.

In example operations, the loop control circuitry 905 supplies a digital value to the DAC 910. The digital value represents an analog voltage to be supplied to the DUT 930. The DAC 910 generates an analog voltage corresponding to the digital value from the loop control circuitry 905. The scaling circuitry 915 amplifies the analog voltage by a gain. The power stage circuitry 920 provides the required current to be delivered to the DUT. In some examples, the power stage circuitry 920 includes driver circuitry, which is structured to increase the drive strength of the supply voltage. In such examples, the power stage circuitry 920 allows the supply of power to the DUT 930 to have a range of different currents. The DUT 930 operates using the supply of power from the power stage circuitry 920. Advantageously, the supply voltage from the power stage circuitry 920 is proportional to the analog voltage from the DAC 910.

The voltage sensing circuitry 935 determines the voltage drop across the variable resistor 925. In example operations, the variable resistor 925 is in line between the power stage circuitry 920 and the DUT 930. In such example operations, the voltage drop across the variable resistor 925 is proportional to the current flowing from the power stage circuitry 920 to the DUT 930. The scaling and filter circuitry 940 amplifies the sense voltage from the voltage sensing circuitry 935 by a gain. In some examples, the gain of the scaling and filter circuitry 940 steps down the sense voltage to be within the range of the CTP ADC circuitry 945. Also, the scaling and filter circuitry 940 filters relatively high frequency changes in the sense voltage to improve a likelihood of the bandwidth of the CTP ADC circuitry 945 accurately converting the amplified sense voltage. The CTP ADC circuitry 945 produces a digital output, which represents the current being supplied to the DUT 930, responsive to the amplified sense voltage from the scaling and filter circuitry 940.

The voltage sensing circuitry 950 determines the voltage drop across the DUT 930. The scaling and filter circuitry 955 amplifies the sense voltage from the voltage sensing circuitry 950 by a gain. In some examples, the gain of the scaling and filter circuitry 955 steps down the sense voltage to be within the range of the CTP ADC circuitry 960. Also, the scaling and filter circuitry 955 filters relatively high frequency changes in the sense voltage to improve a likelihood of the bandwidth of the CTP ADC circuitry 960 accurately converting the amplified sense voltage. The CTP ADC circuitry 960 produces a digital output, which represents the voltage being supplied to the DUT 930, responsive to the amplified sense voltage from the scaling and filter circuitry 955.

In example operations, the loop control circuitry 905 may adjust the supply of power to the DUT 930 responsive to the values from the CTP ADC circuitry 945, 960. In such example operations, the loop control circuitry 905 uses PID control to determine power supply values that efficiently power the DUT 930. Also, the interface circuitry 965 allows external circuitry to receive the values of the CTP ADC circuitry 945, 960 and set values of the loop control circuitry 905. In such examples, the interface circuitry 965 may control the supply of power to the DUT 930.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
a first switch having a first terminal and a second terminal;
analog-to-digital converter (ADC) circuitry having an input and an output, the input of the ADC circuitry coupled to the first terminal of the first switch;
digital-to-analog converter (DAC) circuitry having an input and an output, the input of the DAC circuitry coupled to the output of the ADC circuitry;
combination circuitry having a first input, a second input, and an output, the first input of the combination circuitry coupled to the second terminal of the first switch, the second input of the combination circuitry coupled to the output of the DAC circuitry;
amplifier circuitry having an input and an output, the input of the amplifier circuitry coupled to the output of the combination circuitry; and
a second switch having a terminal coupled to the output of the amplifier circuitry.

2. The apparatus of claim 1, wherein the first switch further has a control terminal, the second switch further has a second terminal, and the apparatus further comprising clock circuitry having a first output and a second output, the first output of the clock circuitry coupled to the control terminal of the first switch, the second output of the clock circuitry coupled to the control terminal of the second switch.

3. The apparatus of claim 1, wherein the combination circuitry includes:
a first resistor having a first terminal and a second terminal, the first terminal of the first resistor is coupled to the second terminal of the first switch; and
a second resistor having a first terminal and a second terminal, the first terminal of the second resistor is coupled to the output of the DAC circuitry, the second terminal of the second resistor is coupled to the input of the amplifier circuitry and the second terminal of the first resistor.

4. The apparatus of claim 1, wherein the amplifier circuitry includes:
an amplifier having an input and an output; and
a resistor having a first terminal and a second terminal, the first terminal of the resistor is coupled to the terminal of the second switch and the output of the amplifier, the second terminal of the resistor is coupled to the output of the combination circuitry.

5. The apparatus of claim 1, wherein the ADC circuitry is first ADC circuitry, the terminal of the second switch is a first terminal, the second switch further having a second terminal, and the apparatus further comprising second ADC circuitry having an input coupled to the second terminal of the second switch.

6. The apparatus of claim 5, wherein the combination circuitry is first combination circuitry, the second ADC circuitry further having an output, and the apparatus further comprising second combination circuitry coupled to the first ADC circuitry and the second ADC circuitry, the second combination circuitry including:
multiplication circuitry having an input and an output, the input of the multiplication circuitry is coupled to the output of the first ADC circuitry; and
addition circuitry having a first input and a second input, the first input of the addition circuitry is coupled to the output of the second ADC circuitry, the second input of the addition circuitry is coupled to the output of the multiplication circuitry.

7. The apparatus of claim 5, wherein the second ADC circuitry further has an output, and the apparatus further comprising:
third ADC circuitry having an input and an output, the input of the third ADC circuitry is coupled to the second terminal of the first switch, the input of the first ADC circuitry, and the first input of the combination circuitry;
comparator circuitry having an input and an output, the input of the comparator circuitry is coupled to the output of the amplifier circuitry and the terminal of the second switch; and
multiplexer circuitry having a first input, a second input, and a control terminal, the first input of the multiplexer circuitry is coupled to the output of the first ADC circuitry and the output of the second ADC circuitry, the second input of the multiplexer circuitry is coupled to the output of the third ADC circuitry, the control terminal of the multiplexer circuitry is coupled to the output of the comparator circuitry.

8. An apparatus comprising:
first analog-to-digital converter (ADC) circuitry having an input and an output;
digital-to-analog converter (DAC) circuitry having an input and an output, the input of the DAC circuitry coupled to the output of the first ADC circuitry;
first combination circuitry having a first input, a second input, and an output, the first input of the first combination circuitry coupled to the input of the first ADC circuitry, the second input of the first combination circuitry coupled to the output of the DAC circuitry;
amplifier circuitry having an input and an output, the input of the amplifier circuitry coupled to the output of the first combination circuitry;
second ADC circuitry having an input and an output, the input of the second ADC circuitry coupled to the output of the amplifier circuitry; and
second combination circuitry having a first input and a second input, the first input of the second combination circuitry coupled to the output of the first ADC circuitry, the second input of the second combination circuitry coupled to the output of the second ADC circuitry.

9. The apparatus of claim 8, further comprising:
a first switch having a first terminal and a second terminal, the first terminal of the first switch is coupled to the input of the first combination circuitry, the second terminal of the first switch is coupled to the input of the first ADC circuitry; and
a second switch having a first terminal and a second terminal, the first terminal of the second switch is coupled to the output of the amplifier circuitry, the second terminal of the second switch is coupled to the input of the second ADC circuitry.

10. The apparatus of claim 8, wherein the first combination circuitry includes:
a first resistor having a first terminal and a second terminal, the first terminal of the first resistor is coupled to the input of the first ADC circuitry; and
a second resistor having a first terminal and a second terminal, the first terminal of the second resistor is coupled to the output of the DAC circuitry, the second terminal of the second resistor is coupled to the input of the amplifier circuitry and the second terminal of the first resistor.

11. The apparatus of claim 8, wherein the amplifier circuitry includes:
an amplifier having an input and an output; and
a resistor having a first terminal and a second terminal, the first terminal of the resistor is coupled to the input of the second ADC circuitry and the output of the amplifier, the second terminal of the resistor is coupled to the output of the first combination circuitry.

12. The apparatus of claim 8, wherein the second combination circuitry includes:
multiplication circuitry having an input and an output, the input of the multiplication circuitry is coupled to the output of the first ADC circuitry; and
addition circuitry having a first input and a second input, the first input of the addition circuitry is coupled to the output of the second ADC circuitry, the second input of the addition circuitry is coupled to the output of the multiplication circuitry.

13. The apparatus of claim 8, further comprising third ADC circuitry having an input coupled to the input of the first ADC circuitry.

14. The apparatus of claim 13, wherein the second combination circuitry further has an output, the third ADC circuitry further has an output, and the apparatus further comprising:
comparator circuitry having an input and an output, the input of the comparator circuitry is coupled to the output of the amplifier circuitry and the input of the second ADC circuitry; and
multiplexer circuitry having a first input, a second input, and a control terminal, the first input of the multiplexer circuitry is coupled to the output of the second combination circuitry, the second input of the multiplexer circuitry is coupled to the output of the third ADC circuitry, the control terminal of the multiplexer circuitry is coupled to the output of the comparator circuitry.

15. An apparatus comprising:
first analog-to-digital converter (ADC) circuitry;
digital-to-analog converter (DAC) circuitry coupled to the first ADC circuitry;
amplifier circuitry coupled to the DAC circuitry, the amplifier circuitry configured to amplify a residue by a gain, the residue is a difference between a first analog value and a second analog value;
second ADC circuitry coupled to the amplifier circuitry; and
combination circuitry coupled to first ADC circuitry and the second ADC circuitry, the combination circuitry configured to:
multiply a first digital value by the gain to produce a combined digital value, the first digital value corresponds to the first analog value;
combine a second digital value and the combined digital value, the second digital value corresponds to the residue; and
generate a third digital value responsive to the combination of the second digital value and the combined digital value.

16. The apparatus of claim 15, further comprising:
a first switch having a first terminal and a second terminal, the first terminal of the first switch coupled to the DAC circuitry and the amplifier circuitry, the second terminal of the first switch coupled to the first ADC circuitry; and
a second switch having a first terminal and a second terminal, the first terminal of the second switch coupled to the amplifier circuitry, the second terminal of the second switch coupled to the second ADC circuitry.

17. The apparatus of claim 16, wherein the first switch further has a control terminal, the second switch further had a control terminal, and the apparatus further comprising clock circuitry configured to:
provide a first clock signal to the control terminal of the first switch; and
provide a second clock signal to the control terminal of the second switch, the second clock signal having a phase different from the first clock signal, the second clock signal having non-overlapping edges with the first clock signal.

18. The apparatus of claim 15, further comprising subtraction circuitry having a first input, a second input, and an output, the first input of the subtraction circuitry coupled to the first ADC circuitry, the second input of the subtraction circuitry coupled to the DAC circuitry, the output of the subtraction circuitry coupled to the amplifier circuitry.

19. The apparatus of claim 15, wherein the first digital value has a first resolution, the second digital value has a second resolution, and the third digital value has a third resolution, the third resolution is greater than the first resolution and the second resolution.

20. The apparatus of claim 15, further comprising:
third ADC circuitry coupled to the first ADC circuitry;
comparator circuitry coupled to the amplifier circuitry and the second ADC circuitry; and
multiplexer circuitry having a first input, a second input, and a control terminal, the first input of the multiplexer circuitry coupled to the combination circuitry, the second input of the multiplexer circuitry coupled to the third ADC circuitry, the control terminal of the multiplexer circuitry coupled to the comparator circuitry.
